(19) United States
(12) Patent Application Publication
(10) Pub. No.: US 2005/0275029 A1
(43) Pub. Date: Dec. 15, 2005

(54) Fast turn-on and low-capacitance SCR ESD protection

(76) Inventor: Jeffrey Watt, Palo Alto, CA (US)

Correspondence Address: MORGAN, LEWIS & BOCKIUS LLP, 1111 PENNSYLVANIA AVENUE, WASHINGTON, DC, 20004, US

(21) Appl. No.: 10/869,712

(22) Filed: Jun. 15, 2004

(51) Int. Cl. H01L 23/62

(52) U.S. Cl. 257/355

(57) ABSTRACT

An ESD protection device comprises a PNP and an NPN transistor having a common PN junction, first and second collector resistances, series connected at a first node, connected to a collector of the PNP transistor, third and fourth collector resistances, series connected at a second node, connected to a collector of the NPN transistor and a trigger circuit connected between the first node and the second node.

### BACKGROUND OF THE INVENTION

The silicon-controlled-rectifier (SCR) is one of the most effective electrostatic discharge (ESD) protection devices available in CMOS technology. Its high current capability and low on-resistance enable the SCR to achieve ESD requirements in a relatively small area. The small area required for the SCR results in a low capacitance and makes it suitable to provide protection for high-speed, low-capacitance input pins.

A version of an SCR ESD protection device called the low-voltage triggering SCR (LVTSCR) is shown in physical device cross-section in FIG. 1 and in circuit schematic in FIG. 2. See A. Chatterjee and T. Polgreen, “A low-voltage triggering SCR for on-chip ESD protection at output and input pads,” IEEE Electron Device Lett., vol. 12, pp. 21-22 (January 1991). As shown in FIG. 1, LVTSCR 10 comprises an N-well 20 formed in a P-substrate 30. A PN junction 25 is formed at the boundary between N-well 20 and P-substrate 30. A polysilicon gate 35 is formed on an oxide layer (not shown) on an upper surface 32 of P-substrate 30. A first N+ diffusion provides an ohmic contact with N-well 20. A second N+ diffusion 42 is formed in P-substrate 30 at surface 32. A third N+ diffusion 44 bridges the N-well/P-substrate boundary. A first P+ diffusion 50 is formed in N-well 20 at surface 32 and a second P+ diffusion 52 provides an ohmic contact with P-substrate 30.

The first N+ diffusion 40 and the first P+ diffusion 50 are connected to Pad 60. Gate 35, N+ diffusion 42 and P+ diffusion 52 are connected to Vss, which ordinarily is ground voltage. Gate 35 and N+ diffusions 42 and 44 form the gate, source, and drain, respectively, of an NMOS transistor and the connection between gate 35 and N+ diffusion 42 makes the transistor a gated diode. P+ diffusion 50, N-well 20 and P-substrate 30 form a PNP transistor; and N+ diffusion 42, P-substrate 30 and N-well 20 form a NPN transistor. As will be apparent, the PNP and NPN transistors have PN junction 25 in common. In addition, the PNP transistor has a collector resistance determined by the resistivity of the P-substrate and the path from the PN junction 25 to P+ diffusion 52; and the NPN transistor has a collector resistance determined by the resistivity of N-well 20 and the path from the PN junction 25 to N+ diffusion 40.

FIG. 2 is a circuit schematic 100 for the physical device of FIG. 1. The schematic comprises a PNP transistor 110 having an emitter connected to Pad 60 and a collector connected through a collector resistance 112 to Vss, an NPN transistor 120 having an emitter connected to Vss and a collector connected through a collector resistance 122 to Pad 60, and a gated diode 130 having a gate connected to Vss and its source and drain connected to the emitter and collector of the NPN transistor. The emitter, base and collector of PNP transistor 110 are realized in the physical device of FIG. 1 by P+ diffusion 50, N-well 20 and P-substrate 30, respectively. Accordingly, the emitter, base and collector of PNP transistor 110 have been numbered 50, 20 and 30, respectively, in FIG. 2. The emitter, base and collector of NPN transistor 120 are realized in the physical device of FIG. 1 by N+ diffusion 42, P-substrate 30 and N-well 20, respectively. Accordingly, the emitter, base and collector of NPN transistor 120 have been numbered, 42, 30, and 20, respectively, in FIG. 2. Gated diode 130 is realized in the physical device of FIG. 1 by the NMOS transistor and its source, drain and gate are realized by N+ diffusion 42, N+ diffusion 44 and gate 35, respectively. Accordingly, the source, drain and gate of gated diode 130 have been numbered 42, 44 and 35, respectively.

The LVTSCR is triggered into the low-impedance on state by the gated diode breakdown of the N+ diffusion 44 bridging the N-well/P-substrate boundary. The gated diode breakdown raises the potential of the P-substrate 30, forward biasing the emitter 42 of NPN transistor 120. The gated diode breakdown also causes a current flow through the N-well 20 from the Pad-connected N+ diffusion 40 which forward biases the emitter 50 of PNP transistor 110. The result is that the SCR latches up into the low-impedance state.

One problem with this SCR structure is that the turn-on time may be too slow for fast ESD events such as those modeled by the charged device model (CDM). See, A. Amerasekera and C. Duvvury, ESD in Silicon Integrated Circuits, pp. 28-40 (2^{nd} ed. 2002). The relatively large spacing between the Vss-connected N+ diffusion 42 and Pad-connected P+ diffusion 50 due to the presence of the bridging N+ diffusion 44 and grounded gate NMOS 130 contributes to the slow turn-on.

The SCR structure shown in FIG. 3 and FIG. 4 was developed to reduce the turn-on time. These figures are based on FIGS. 7 and 6, respectively, of U.S. Pat. No. 5,825,600 which is incorporated herein by reference. As shown in FIG. 3, SCR structure 310 comprises an N-well 320 formed in a P-substrate 330. A PN junction 325 is formed at the boundary between N-well 320 and P-substrate 330. A polysilicon gate 335 is formed on an oxide layer (not shown) on an upper surface 332 of P-substrate 330. A first N+ diffusion 340 provides an ohmic contact with N-well 320. Second and third N+ diffusions 342 and 344 are formed in P-substrate 330 at surface 332. A fourth N+ diffusion 346 provides an ohmic contact with N-well 320. A first P+ diffusion 350 is formed in N-well 320 at surface 332 and a second P+ diffusion 352 provides an ohmic contact with P-substrate 330.

The first N+ diffusion 340 and the first P+ diffusion 350 are connected to Pad 360. Gate 335, N+ diffusion 342 and P+ diffusion 352 are connected to Vss, which ordinarily is ground voltage. Gate 335 and N+ diffusions 342 and 344 form the gate, source and drain, respectively, of an NMOS transistor and the connection between gate 335 and N+ diffusion 342 makes the transistor a gated diode. N+ diffusion 344 is connected through N+ diffusion 346 and N-well 320 to Pad 360. P+ diffusion 350, N-well 320 and P-substrate 330 form a PNP transistor; and N+ diffusion 342, P-substrate 330 and N-well 320 form a NPN transistor. As will be apparent, the PNP and NPN transistors have PN junction 325 in common. In addition, the PNP transistor has a collector resistance determined by the resistivity of the P-substrate and the path from the PN junction 325 to P+ diffusion 352; and the NPN transistor has a collector resistance determined by the resistivity of N-well 320 and the path from the PN junction 325 to N+ diffusion 340.

FIG. 4 is a circuit schematic 400 for the physical device of FIG. 3. The schematic comprises a PNP transistor 410 having an emitter connected to Pad 360 and a collector connected through a collector resistance 412 to Vss, an NPN transistor 420 having an emitter connected to Vss and a collector connected through collector resistances 424 and 426 to Pad 360, and a gated diode 430 having a gate connected to Vss, its source connected to the emitter of the NPN transistor and its drain connected to an intermediate node 425 between collector resistances 424 and 426. The emitter, base and collector of PNP transistor 410 are realized in the physical device of FIG. 3 by P+ diffusion 350, N-well 320 and P-substrate 330, respectively. Accordingly, the emitter, base and collector of PNP transistor 410 have been numbered 350, 320 and 330, respectively, in FIG. 4. The emitter, base and collector of NPN transistor 420 are realized in the physical device of FIG. 3 by N+ diffusion 342, P-substrate 330 and N-well 320, respectively. Accordingly, the emitter, base and collector of NPN transistor 420 have been numbered, 342, 330, and 320, respectively, in FIG. 4. Gated diode 430 is realized in the physical device of FIG. 3 by the NMOS transistor and its source, drain and gate are realized by N+ diffusion 342, N+ diffusion 344 and gate 335, respectively. Accordingly, the source, drain and gate of gated diode 330 have been numbered 342, 344 and 335, respectively.

The Vss-connected N+ diffusion 342 and the Pad-connected P+ diffusion 350 are placed at the minimum separation allowed by the technology design rules. The drain 344 of the NMOS transistor 430 is connected to Pad 360 through a portion of the N-well 320. As a result, the PNP and NPN transistors 410 and 420 are simultaneously turned on when the gated diode 430 breaks down. The small separation between N+ diffusion 342 and P+ diffusion 350 and the simultaneous PNP and NPN triggering minimize the turn-on time of this SCR structure.

The SCR protection device shown in FIG. 3 and FIG. 4 improves the response time so that acceptable performance can be achieved for the CDM ESD test. Nevertheless, there are several problems with this improved structure:

1. The gated diode implemented in the grounded gate NMOS transistor 430 extends across the entire width of the SCR structure which adds a significant amount of capacitance to the structure.

2. The trigger voltage of the SCR is determined by the NMOS grounded gate breakdown voltage which may not be compatible with the requirements of the input buffer being protected. The SCR needs to trigger at a voltage low enough to avoid damage to the input buffer but not so low that the SCR can be triggered into the low impedance state during normal operation. The grounded gate NMOS trigger device may not meet these requirements.

3. The resistance between the two N+ diffusions 340 and 346 in the N-well must be large enough to ensure that the PNP transistor 410 is triggered by the current flow created by breakdown of the grounded gate NMOS transistor 430. If the N-well resistance is optimized based on other device requirements, the only way to increase the resistance between the N+ diffusions is to increase the spacing between them. If the spacing is large, the area efficiency of the structure is poor and the capacitance may be substantially degraded.

### SUMMARY OF THE INVENTION

As illustrative embodiment of the ESD protection device of the present invention comprises a PNP and an NPN transistor having a common PN junction, first and second collector resistances, series connected at a first node, connected to a collector of the PNP transistor, third and fourth collector resistances, series connected at a second node, connected to a collector of the NPN transistor, and a trigger circuit connected between the first node and the second node.

### BRIEF DESCRIPTION OF DRAWING

FIG. 1 is a cross-section of a prior art LVTSCR;

FIG. 2 is a circuit schematic for the device of FIG. 1;

FIG. 3 is a cross-section of a prior art SCR device;

FIG. 4 is a circuit schematic for the device of FIG. 3;

FIG. 5 is a cross-section of an improved excessive charge protection device of the present invention;

FIG. 6 is a circuit schematic for the device of FIG. 5;

FIGS. 7A-7C are circuit schematics depicting alternative embodiments of a feature of the device and circuit schematic of FIGS. 5 and 6;

FIG. 8 is a cross-section depicting implementation details for the device of FIG. 5;

FIG. 9 is a layout for the device of FIG. 8;

FIG. 10 is a cross-section depicting an improvement in the device of FIG. 8;

FIG. 11 is a layout for the device of FIG. 10;

FIG. 12 is a circuit schematic for the device of FIG. 10; and

FIG. 13 is a cross-section of the device of FIG. 10 surrounded by a guardring.

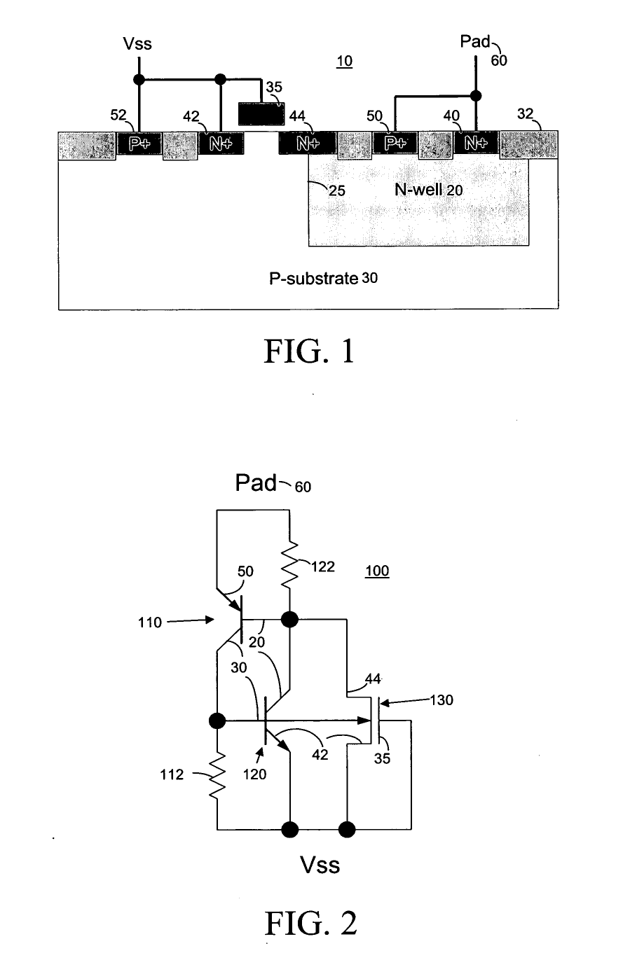

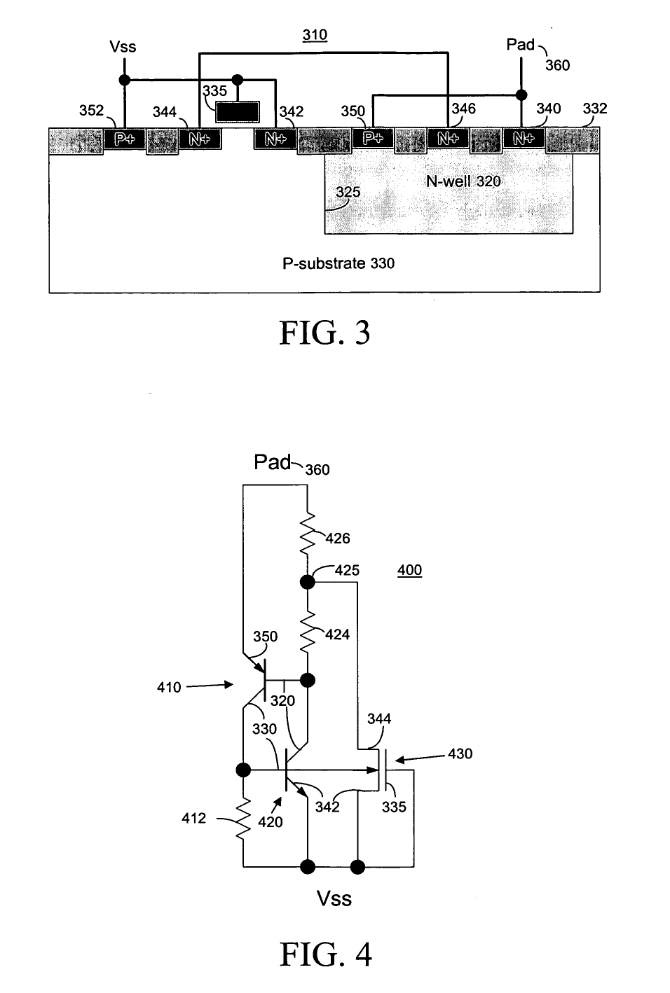

### DETAILED DESCRIPTION OF PREFERRED EMBODIMENT

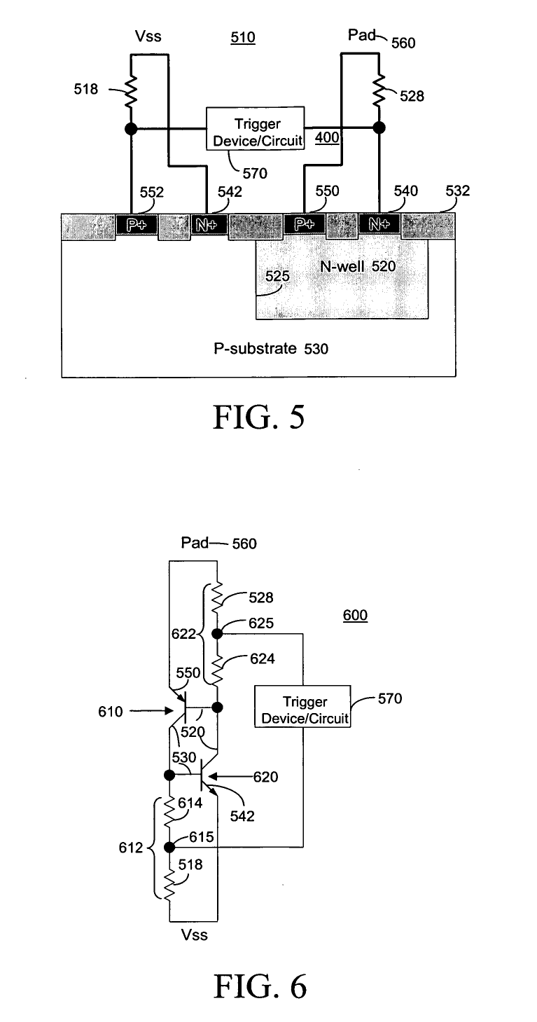

The present invention is shown in the physical device cross section of FIG. 5 and the equivalent circuit schematic of FIG. 6. As shown in FIG. 5, an excessive charge prevention device 510 comprises an N-well 520 formed in a P-substrate 530. A PN junction 525 is formed at the boundary between N-well 520 and P-substrate 530. A first N+ diffusion 540 provides an ohmic contact with N-well 520. A second N+ diffusion 542 is formed in an upper surface 532 of P-substrate 530. A first P+ diffusion 550 is formed in N-well 520 at surface 532 and a second P+ diffusion 552 provides an ohmic contact with P-substrate 530. The first N+ diffusion 540 and the first P+ diffusion 550 are connected to Pad 560 with N+ diffusion 540 being connected to Pad 560 through a first resistor 528. The second N+ diffusion 542 and P+ diffusion 552 are connected to Vss, which ordinarily is ground voltage, with P+ diffusion 552 being connected to Vss through a second resistor 518. A trigger device or circuit 570 is connected between first N+ diffusion 540 and second P+ diffusion 552.

P+ diffusion 550, N-well 520 and P-substrate 530 form a PNP transistor; and N+ diffusion 542, P-substrate 530 and N-well 520 form a NPN transistor. As will be apparent, the PNP and NPN transistors have PN junction 525 in common. In addition, the PNP transistor has a collector resistance determined in part by second resistor 518 and in part by the resistivity of the P-substrate 530 and the path from the PN junction 525 to P+ diffusion 552; and the NPN transistor has a collector resistance determined in part by first resistor 528 and in part by the resistivity of the N-well 520 and the path from the PN junction 525 to N+ diffusion 540.

FIG. 6 is a circuit schematic 600 for the physical device of FIG. 5. The schematic comprises a PNP transistor 610 having an emitter connected to Pad 560 and a collector connected through a collector resistance 612 to Vss, an NPN transistor 620 having an emitter connected to Vss and a collector connected through a collector resistance 622 to Pad 560, and a trigger device or circuit 570. Collector resistance 612 comprises resistors 614 and 518 and collector resistance 622 comprises resistors 624 and 528. At least resistors 614 and 624 are realized within P-substrate 530 and N-well 520. The emitter, base and collector of PNP transistor 610 are realized in the physical device of FIG. 5 by P+ diffusion 550, N-well 520 and P-substrate 530, respectively. Accordingly, the emitter, base and collector of PNP transistor 610 have been numbered 550, 520 and 530, respectively, in FIG. 6. The emitter, base and collector of NPN transistor 620 are realized in the physical device of FIG. 5 by N+ diffusion 542, P-substrate 530 and N-well 520, respectively. Accordingly, the emitter, base and collector of NPN transistor 520 have been numbered, 542, 530, and 520, respectively, in FIG. 6. Trigger device/circuit 570 is connected between a node 615 between resistors 518 and 614 and a node 625 between resistors 528 and 624.

Minimum spacing allowed by design rules is used between the Vss-connected N+ diffusion 552 and the Pad-connected P+ diffusion 550 to minimize turn-on delay and on resistance. Under normal operation when the SCR is in the off state, trigger device/circuit 570 has a high impedance and does not allow enough current flow to create any significant voltage drop across the resistors 518, 528. This keeps the base-emitter voltage of both PNP and NPN transistors 610, 620 near zero volts which keeps the SCR in the off state. When the device is triggered into the on-state, trigger device/circuit 570 has a low impedance and current flows between Pad and Vss through the resistors 518, 528. This produces a significant voltage drop across both the NPN and PNP base-emitter junctions (i.e. between Vss-connected N+ diffusion 542 and P+ diffusion 552 in P-substrate 530 and between Pad-connected P+ diffusion 550 and N+ diffusion 540 in N-well 520). The forward bias across the base-emitter junctions turns on the PNP and NPN transistors 610 and 620 and causes the SCR to latch into the low-impedance on state. The small spacing between Pad-connected P+ diffusion 550 and Vss-connected N+ diffusion 542 and the simultaneous triggering of the PNP and NPN transistors 610, 620 results in a fast response time for this SCR structure.

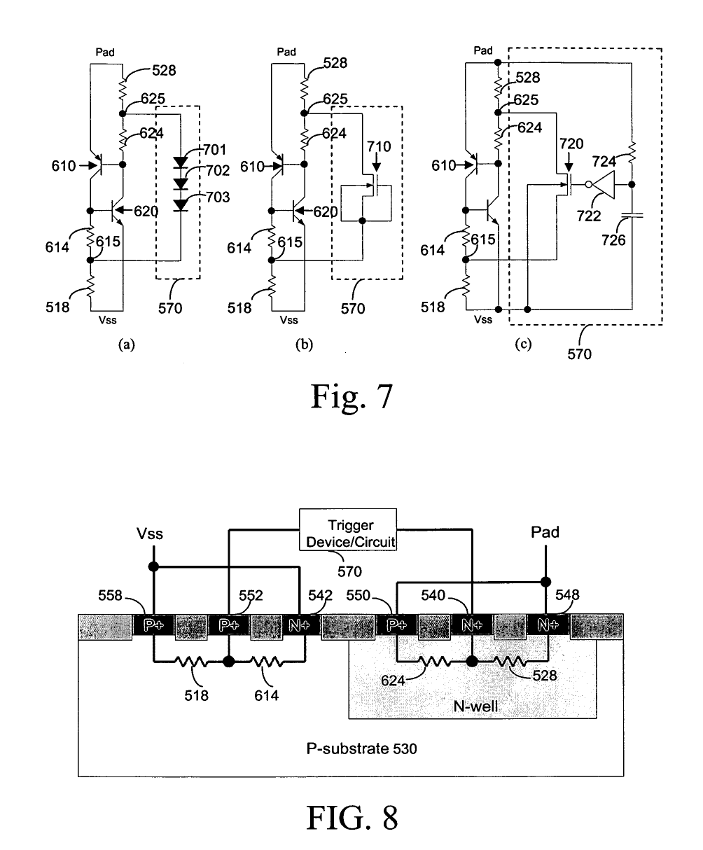

There are many options for the trigger device/circuit 570 depending on the requirements for the input pin being protected. A few options are illustrated in FIGS. 7A-7C. FIG. 7A depicts a diode stack trigger of three series-connected diodes 701, 702, 703 connected between nodes 616 and 625. The diode stack trigger can be implemented with P+/N-well diodes or P-well/N+ within deep N-well diodes. The number of diodes in the stack can be adjusted to achieve the desired trigger voltage. FIG. 7B depicts a grounded gate NMOS trigger device 710 connected between nodes 615 and 625. It can be implemented either with an NMOS in P-substrate or with an NMOS in P-well within deep N-well. The latter approach allows both the NMOS source and bulk connections to be connected through resistor 518 as shown in FIG. 7B which can reduce the SCR turn-on time. The option shown in FIG. 7B can achieve lower capacitance than the structure described in U.S. Pat. No. 5,825,600 since the grounded gate NMOS width can be smaller than the width of the SCR. FIG. 7C depicts an NMOS trigger device 720 that is turned on by an inverter 722 when a fast voltage ramp appears on the Pad. The NMOS device is connected between nodes 615 and 625. A resistor 724 and a capacitor 726 are connected in series between Pad and Vss and the inverter 722 is connected to a node 725 between resistor 724 and capacitor 726. The time constant of the RC network connected to the inverter input can be tuned so that it responds to fast voltage ramps characteristic of CDM ESD but not to slower voltage ramps which occur during normal operation.

Resistors 518 and 528 can be implemented using polysilicon, diffusion or well resistors. The resistors may also be integrated into the SCR structure as shown in FIG. 8. FIG. 8 is the same as the cross-section of FIG. 5, except that a third N+ diffusion 548 forms another ohmic contact in N-well 520, a third P+ diffusion 558 forms another ohmic contact in P-substrate 530. Resistor 518 is accordingly the resistance along the path through substrate 530 between diffusions 552 and 558 and resistor 528 is the resistance through the N-well 520 along the path between diffusions 540 and 548. This approach, however, may not result in the most area efficient structure if a large spacing must be used between the two N+ diffusions 540, 548 or the two P+ diffusions 552, 558 to achieve the desired resistance.

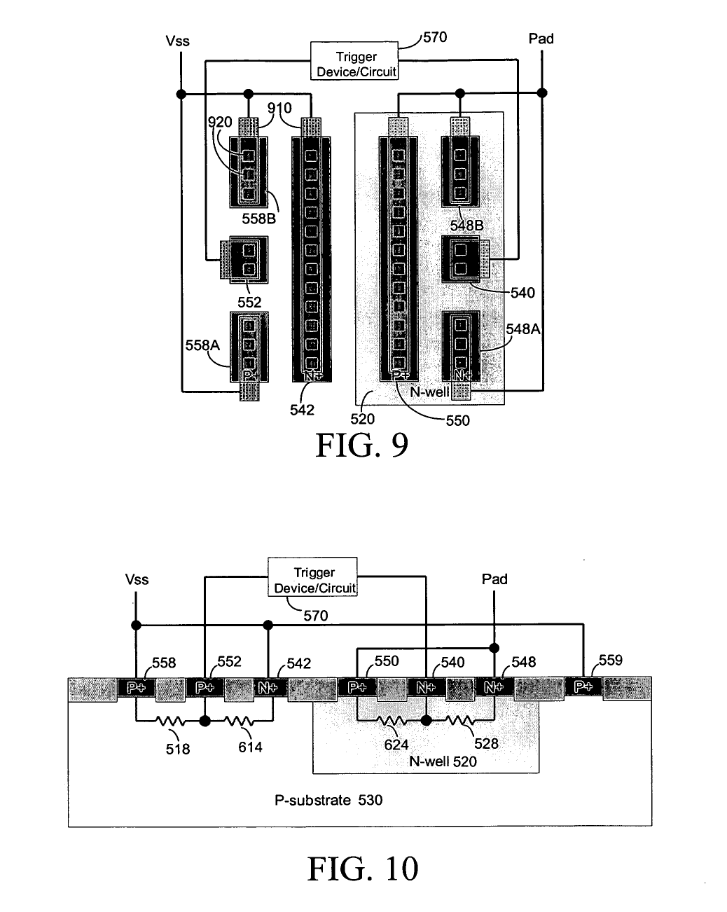

An area efficient implementation of integrated resistors 518 and 528 is shown in the layout of FIG. 9. The layout depicts the physical locations of N-well 520, the N+ diffusions 540, 542, 548, and the P+ diffusions 550, 552, 558 on the surface of the substrate. Also shown are the conductive leads 910 to the various diffusions and the contacts 920 between the leads and the diffusions. In this layout, the Vss-connected P+ diffusion 558 and the Pad-connected N+ diffusion 548 are both divided into multiple segments and the P+ diffusion 552 and the N+ diffusion 542 are placed between these segments. In particular, the P+ diffusion 552 is placed in a gap between two segments 558A and 558B of the Vss-connected P+ diffusion 558. The Vss-connected P+ diffusion 558 could also be divided into more than two segments with a P+ diffusion 552 placed in each of the breaks between segments. The resistance 518 is determined by the number of P+ diffusions 552 and the spacing between the P+ diffusions 552 and the segments of the Vss-connected diffusion 558. The layout of the Pad-connected N+ diffusion 548 and the N+ diffusion 540 is similar to the P+ diffusion layout. This layout style avoids the use of two parallel strips of P+ and N+ diffusions which saves significant area over the fast turn-on SCR structure of FIG. 8. As described below, it also enables the integration of a Pad to Vss diode into the structure for negative ESD protection.

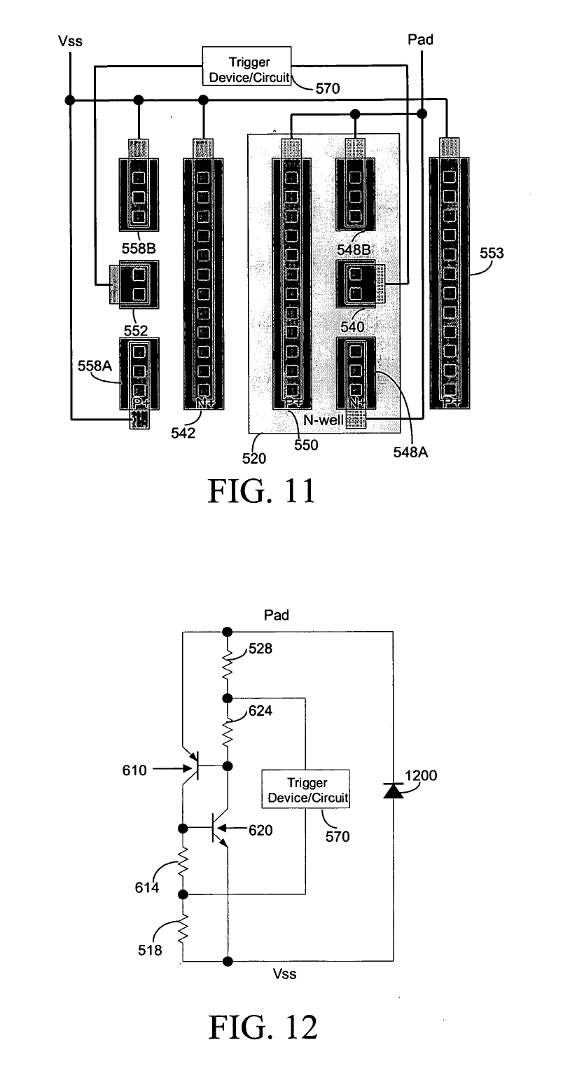

The SCR structure as described so far provides effective protection against ESD discharges which create a positive potential on the Pad with respect to Vss. For negative ESD discharges, the SCR structure shown in FIG. 8 and FIG. 9 contains an N-well/P-substrate diode between the Pad and Vss which will be forward biased during a negative ESD event and provide some protection. However, because of the relatively large distance between the Pad-connected N+ diffusion 548 and the Vss-connected P+ diffusion 558, the series resistance of this diode may be too large. A much more efficient diode can be realized as shown in FIG. 10 by placing a Vss-connected P+ diffusion 559 immediately adjacent to the side of the N-well 520 which contains the Pad-connected N+ diffusion 548. The area efficient version of the structure is shown by the layout in FIG. 11. The layout is the same as that of FIG. 9 except that it depicts P+ diffusion 559 on the right-hand side of N-well 520. The equivalent circuit for the SCR with a Pad to Vss diode 1200 is shown in FIG. 12.

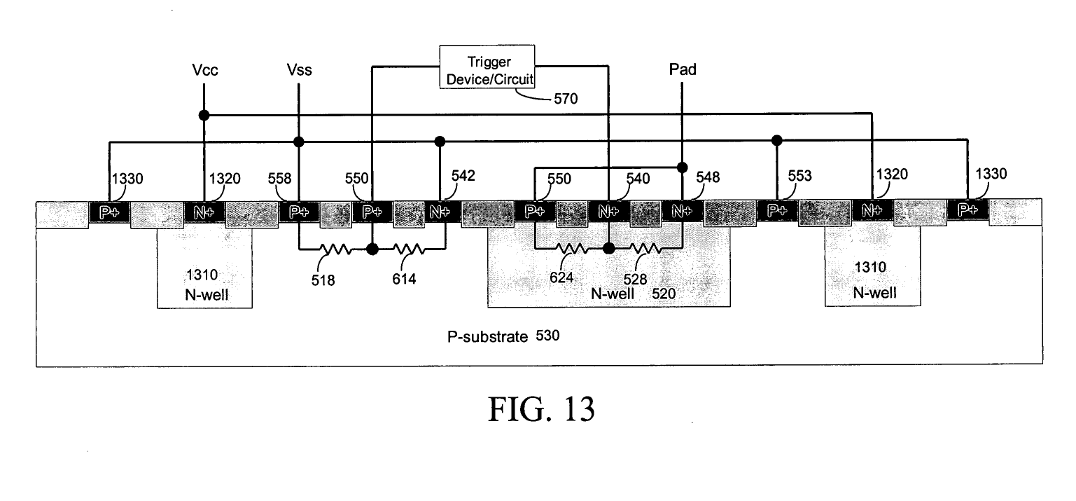

Unintended latchup during normal operation is a concern with any SCR ESD protection device. To prevent latchup, the SCR structure needs to be surrounded by guardrings as shown in FIG. 13 to prevent latchup due to current injection for sources external to the SCR structure. In particular, the guardring comprises an additional N-well 1310 formed in P-substrate 530 on the periphery of the structures shown previously in FIG. 10, an N+ diffusion 1320 making ohmic contact with N-well 1310 and being connected to Vcc and an additional P+ diffusion 1330 on the periphery of N-well 1310 making ohmic contact with substrate 530 and being connected to Vss. To provide the guardring, the N+ diffusion 1320/N-well 1310 connected to Vcc and the outer P+ diffusion 1330 connected to Vss extend in a continuous rectangular ring surrounding the entire structure.

The invention can achieve lower capacitance than the prior art by using a smaller trigger device and has more flexibility in the trigger mechanism used to turn on the SCR. Compared to the prior art, a more efficient layout is used for the N-well diffusions, which reduces area and capacitance. The use of minimum spacing between the N+ diffusion 542 and P+ diffusion 550 and the simultaneous triggering of NPN and PNP transistors maintains the fast turn-on capability of the prior art. Also, the ability to use resistors 518 and 528 implemented in polysilicon or diffusion removes the restriction imposed by using integrated well resistors in the prior art and enables reduced structure area and capacitance.

As will be apparent to those skilled in the art, numerous variations of the embodiments described above may be implemented within the spirit and scope of the claims.

1. An apparatus for protecting a semiconductor device from excessive charge comprising:
a PNP transistor and an NPN transistor formed in a semiconductive substrate, said transistors having a common PN junction;
first and second collector resistances, series connected at a first node, said first resistance also being connected to a collector of said PNP transistor;
third and fourth collector resistances, series connected at a second node, said third resistance also being connected to a collector of said NPN transistor; and
a trigger circuit connected between said first node and said second node.

2. The apparatus of claim 1 wherein the first collector resistance is formed in said semiconductive substrate.

3. The apparatus of claim 2 wherein the third collector resistance is formed in said semiconductive substrate.

4. The apparatus of claim 1 wherein said first and second collector resistances are formed in said semiconductive substrate.

5. The apparatus of claim 4 wherein said third and fourth collector resistances are formed in said semiconductive substrate.

6. The apparatus of claim 1 wherein the third collector resistance is formed in said semiconductive substrate.

7. The apparatus of claim 1 wherein the third and fourth collector resistances are formed in said semiconductive substrate.

8. The apparatus of claim 1 wherein the trigger circuit comprises a plurality of diodes connected in series between the first node and the second node.

9. The apparatus of claim 1 wherein the trigger circuit comprises a grounded gate NMOS device connected between the first node and the second node.

10. The apparatus of claim 1 wherein the trigger circuit comprises an NMOS transistor having a source and drain connected between the first node and the second node, an inverter connected to the gate of the NMOS transistor, and an input to the inverter connected to a node between a resistor and a capacitor that are connected in series between an emitter of the PNP transistor and an emitter of the NPN transistor.

11. The apparatus of claim 1 further comprising a diode connected between an emitter of the PNP transistor and an emitter of the NPN transistor.

12. The apparatus of claim 1 further comprising a guardring surrounding the apparatus.

13. An apparatus for protecting a semiconductor device from excessive charge comprising:
a substrate having a first conductivity type;
a well region formed in said substrate, said well region having a second conductivity type opposite to said first conductivity type;
a first ohmic contact to said substrate;
a second ohmic contact to said well region;
a first diffusion region in said substrate having the second conductivity type;
a second diffusion region in said well region having the first conductivity type;
a first resistor connected between said first ohmic contact and said first diffusion region;
a second resistor connected between said second ohmic contact and said second diffusion region; and
a trigger circuit connected between the first ohmic contact and the second ohmic contact.

14. The apparatus of claim 13 wherein the first conductivity type is P and the second conductivity type is N.

15. The apparatus of claim 14 wherein the first diffusion region, the substrate and the well region form an NPN transistor.

16. The apparatus of claim 15 wherein the second diffusion region, the well region and the substrate form a PNP transistor that shares a PN junction with the NPN bipolar transistor.

17. The apparatus of claim 14 wherein the second diffusion region, the well region and the substrate form a PNP transistor.

18. The apparatus of claim 13 wherein the first resistor is formed in the substrate.

19. The apparatus of claim 13 wherein the second resistor is formed in the well region.

20. The apparatus of claim 13 wherein the trigger circuit comprises a plurability of diodes connected in series between the first ohmic contact and the second ohmic contact.

21. The apparatus of claim 13 wherein the trigger circuit comprises a grounded gate NMOS device connected between the first ohmic contact and the second ohmic contact.

22. The apparatus of claim 13 wherein the trigger circuit comprises an NMOS transistor having a source and drain connected between the first ohmic contact and the second ohmic contact, an inverter connected to the gate of the NMOS transistor, and an input to the inverter connected to a node between a resistor and a capacitor that are connected in series between the first diffusion region and the second diffusion region.

23. The apparatus of claim 13 further comprising a diode connected between the first diffusion region and the second diffusion region.

24. The apparatus of claim 13 further comprising a guardring surrounding the apparatus.

25. An apparatus for protecting a semiconductor device from excessive charge comprising:
a substrate having a first conductivity type;
a well region formed in said substrate, said well region having a second conductivity type opposite to said first conductivity type;
a first ohmic contact to said substrate;
a second ohmic contact to said well region;
a third ohmic contact to said well region;
in said substrate, a first diffusion region having the second conductivity type;
in said well region, a second diffusion region having the first conductivity type;
a first resistor connected between said first ohmic contact and said first diffusion region; and
a trigger circuit connected between the first ohmic contact and the second ohmic contact.

26. An apparatus for protecting a semiconductor device from excessive charge comprising:
a substrate having a first conductivity type;
a well region formed in said substrate, said well region having a second conductivity type opposite to said first conductivity type;
a first ohmic contact to said substrate;
a second ohmic contact to said well region;
a third ohmic contact to said substrate;
in said substrate, a first diffusion region having the second conductivity type;
in said well region, a second diffusion region having the first conductivity type;
a first resistor connected between said second ohmic contact and said second diffusion region; and
a trigger circuit connected between the first ohmic contact and the second ohmic contact.

27. A method of protecting a semiconductor device from excessive charge comprising:
forming in a substrate having a first conductivity type a well region having a second conductivity type opposite to said first conductivity type;
forming a first ohmic contact to said substrate;
forming a second ohmic contact to said well region;
forming in said substrate a first diffusion region having the second conductivity type;
forming in said well region a second diffusion region having the first conductivity type;
wherein the first diffusion region, the substrate and the well region form a first bipolar transistor and the second diffusion region, the well region and the substrate form a second bipolar transistor;
connecting a first resistor between said first ohmic contact and said first diffusion region
connecting a second resistor between said second ohmic contact and said second diffusion region; and
connecting a trigger circuit between the first ohmic contact and the second ohmic contact, whereby when excessive charge triggers the trigger circuit current flows through the first and second resistors, thereby latching the lateral and vertical bipolar transistors into a low impedance state.

28. The method of claim 27 wherein the first conductivity type is P and the second conductivity type is N.

29. The method of claim 27 wherein the first bipolar transistor is an NPN transistor.

30. The method of claim 27 wherein the first bipolar transistor is a NPN transistor and the second bipolar transistor is a PNP transistor.

31. The method of claim 27 wherein the first resistor is formed in the substrate.

32. The method of claim 27 wherein the second resistor is formed in the well region.

33. The method of claim 27 wherein the trigger circuit comprises a plurality of diodes connected in series between the first ohmic contact and the second ohmic contact.

34. The method of claim 27 wherein the trigger circuit comprises a grounded gate NMOS device connected between the first ohmic contact and the second ohmic contact.

35. The method of claim 27 wherein the trigger circuit comprises an NMOS transistor having a source and drain connected between the first ohmic contact and the second ohmic contact, an inverter connected to the gate of the NMOS transistor, and an input to the inverter connected to a node between a resistor and a capacitor that are connected in series between the first diffusion region and the second diffusion region

36. The method of claim 27 further comprising the step of connecting a diode between the first diffusion region and the second diffusion region.
